(19) United States
(12) Patent Application Publication
(10) Pub. No.: US 2015/0318169 A1
(43) Pub. Date: Nov. 5, 2015

(54) METHODS OF FORMING EPITAXIAL SEMICONDUCTOR CLADDING MATERIAL ON FINS OF A FINFET SEMICONDUCTOR DEVICE

(71) Applicant: GLOBALFOUNDRIES Inc., Grand Cayman (KY)

(72) Inventors: Yi Qi, Niskayuna, NY (US); Ajey Poovannummoottil Jacob, Watervliet, NY (US); Jody A. Fronheiser, Delmar, NY (US); Murat Kerem Akarvardar, Saratoga Springs, NY (US); David Paul Brunco, Latham, NY (US)

(73) Assignee: GLOBALFOUNDRIES Inc., Grand Cayman (KY)

(21) Appl. No.: 14/267,634

(22) Filed: May 1, 2014

(51) Int. Cl. H01L 21/02; H01L 29/161; H01L 29/66

(52) U.S. Cl. CPC H01L 21/0262; H01L 29/66818; H01L 29/66795; H01L 29/161; H01L 21/02532

(57) ABSTRACT

One illustrative method disclosed herein includes, among other things, forming a fin in a semiconductor substrate and performing an epitaxial deposition process using a combination of silane (SiH₄), dichlorosilane (SiH₂Cl₂), germane (GeH₄) and a carrier gas to form an epi semiconductor material around the fin, wherein the flow rate of dichlorosilane used during the epitaxial deposition process is equal to 10-90% of the combined flow rate of silane and dichlorosilane.

### BACKGROUND OF THE INVENTION

1. Field of the Invention

Generally, the present disclosure relates to the manufacture of FET semiconductor devices, and, more specifically, to various methods of forming epitaxial semiconductor cladding material on fins of a FinFET semiconductor device.

2. Description of the Related Art

A conventional FinFET device has a three-dimensional (3D) structure that includes one or more vertically oriented fins that are formed in a semiconductor substrate. FIGS. 1A (cross-sectional view) and 1B (plan view) depict a FinFET device 10 at a point in fabrication where a plurality of trenches 19 were formed in a standard (100) silicon substrate 12 to define the initial structure of the simplistically depicted fins 14, having sidewalls 14S and an upper surface 14U. After the trenches 19 were formed, a layer of insulating material 22, such as silicon dioxide, was formed so as to overfill the trenches 19. Thereafter, a chemical mechanical polishing (CMP) process was performed to planarize the upper surface of the insulating material 22 with the top of the fins 14 (or the top of a patterned hard mask). Thereafter, an etch-back process was performed to recess the layer of insulating material 22 between the fins 14 and thereby expose the upper portions of the fins 14, which corresponds to the final fin height of the fins 14. As depicted, the fins 14 have a three-dimensional configuration: an exposed height 14H, a width 14W and an axial length or centerline 14L (see FIG. 1B). The axial length direction 14L corresponds to the direction of current travel in the device 10 when it is operational.

In one illustrative process flow, after the fins 14 are formed, a gate structure (not shown) is formed over a portion of the axial length of the fins 14, a portion of the fins 14 that will become the channel region for the device 10. Next, sidewalls spacers (not shown) are formed adjacent the gate structure. The portions of the fins 14 that are positioned outside of the spacers 18 will become part of the source/drain regions for the device 10. The portions of the fins 14 that are in the source/drain regions may be increased in size or even merged together (a situation not shown in FIGS. 1A-B) by performing one or more epitaxial growth processes. The process of increasing the size of or merging the fins 14 in the source/drain regions of the device 10 is performed to reduce the resistance of source/drain regions and/or make it easier to establish electrical contact to the source/drain regions. Even if an epi “merge” process is not performed, an epi growth process will typically be performed on the fins 14 to increase their physical size.

As indicated in FIGS. 1A-1B, for a (100) silicon substrate 12, in traditional manufacturing techniques, the substrate 12 is oriented during manufacturing of the device 10 such that the sidewalls 14S of the fins 14 are oriented in the <110> direction, while the long axis 14L of the fins 14 is also oriented in the <110>. As used herein, the “< >” designation reflects an identification of a family of crystallographically equivalent directions. Of course, in the case where the fins 14 have a tapered cross-sectional configuration as opposed to the idealized rectangular cross-sectional configuration shown in FIGS. 1A-B, the sidewalls 14S of such tapered fins may be positioned slightly out of the <110> direction due to the tapered shape of the tapered fins.

In FinFET devices, so-called epi cladding semiconductor material, e.g., epi SiGe, may be formed in the channel region of the device, in the source/drain regions of the device or both. With reference to FIG. 1C, due to the crystallographic orientation of a standard (100) silicon substrate 12, and the orientation of the fins 14 formed on such a substrate, the additional epi cladding semiconductor material 24 will form so as to exhibit a general, idealized, diamond-shaped configuration. The approximate outline of the original fins 14 is depicted by the dashed line 14X in FIG. 1C for reference purposes only. The formation of the diamond-shaped epi semiconductor material 24 is purely a result of the kinetics of the epi deposition process and the crystallographic orientation of the fins 14. The amount of such epi semiconductor material 24 formed may vary depending upon the device 10 under construction.

The above-described process of forming this additional epi semiconductor material 24 is not without problems. First, the epi semiconductor material 24 grows at different rates on the different crystalline planes of the fin 14 and, therefore, results in the epi semiconductor material having different thicknesses at different locations around the perimeter of the fin 14. Accordingly, when such an epi semiconductor material 24 is used in the channel region of the device 10, there will be undesirable variations in the threshold voltage (Vₜ) of the device. Another problem that may arise when forming the epi semiconductor material 24 in the source/drain regions of the device is, for example, despite best efforts to tightly control the process, the epi semiconductor material 24 may be grown to such an extent that the epi semiconductor material 24 is formed in areas where it should not be located and/or is formed in such quantities that the epi semiconductor material 24 on adjacent fins 14 may undesirably merge with one another. This is especially true in closely-packed device areas such as SRAM areas. Obviously, such unanticipated merging of the epi semiconductor material 24 on the fins 14 can cause the device 10 to function at a lesser level than that anticipated by the design process. In a worst-case scenario, the epi material 24 that is formed on, for example, an NMOS device may inadvertently merge with the epi semiconductor material 24 formed on a fin of a PMOS device (or vice-versa). In such a situation, an electrical short may be created and the device 10 may have to be scrapped.

Efforts have been made to reduce the non-uniform growth of the diamond-shaped epi semiconductor material 24 discussed above. One technique that has been tried to grow epi semiconductor material in a more conformal manner involves orienting the fins 14 in a particular crystallographic orientation. For example, FIGS. 1D, 1E and 1F are TEM photographs of epi silicon-germanium (SiGe_{0.75}) material 30 that was formed on fins formed in silicon substrates having different crystallographic orientations: (a) a non-rotated (100) substrate, e.g., (100)<110>; (b) a non-rotated (110) substrate, e.g., (110)<110>; and (c) a (100) substrate rotated 45°, e.g., (100)<110>; respectively. The epi SiGe_{0.75} material 30 was formed using silane (SiH₄) and germane (GeH₄) as precursor gases. FIG. 1D depicts the formation of real-world diamond-shaped epi SiGe_{0.75} material, as depicted in idealized form in FIG. 1C. As can be seen, relative to the epi silicon-germanium (SiGe_{0.75}) shown in FIG. 1D, the epi silicon-germanium (SiGe_{0.75}) shown in FIGS. 1E and 1F has a more uniform thickness at least on the sidewalls of the fins. However, this technique has drawbacks. In general, the epi silicon-germanium (SiGe_{0.75}) material 30 shown in FIGS. 1D-1F exhibits more uniform and conformal growth as one progresses from FIGS. 1D to 1F, i.e., from left to right. On the other hand, the epi silicon-germanium (SiGe_{0.75}) material 30 exhibits higher electron or hole mobility as one progresses from FIG. 1F to 1D, i.e., from right to left. Thus, there is an inherent and undesirable “trade-off” that must be considered when using this fin crystallographic orientation approach in an attempt to grow a more uniform epi material on the fins of a FinFET device.

What is needed is a method of forming epi semiconductor material in a very conformal manner such that it has more uniform thickness at all locations around the fin. Growth of such a uniform material would perhaps allow the more conformal and uniform-thickness epi material to be used in the channel region of a FinFET device and reduce or eliminate the problems associated with forming the diamond-shaped epi semiconductor material 24 in the source/drain regions of the device. The present disclosure is directed to various methods of forming epitaxial semiconductor cladding material on fins of a FinFET semiconductor device that may solve or reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming epitaxial semiconductor cladding material on fins of a FinFET semiconductor device. One illustrative method disclosed herein includes, among other things, forming a fin in a semiconductor substrate and performing an epitaxial deposition process using a combination of silane (SiH₄), dichlorosilane (SiH₂Cl₂), germane (GeH₄) and a carrier gas to form an epi semiconductor material around the fin, wherein the flow rate of dichlorosilane used during the epitaxial deposition process is equal to 10-90% of the combined flow rate of silane and dichlorosilane.

Another illustrative embodiment includes, among other things, forming a fin in a (100) silicon substrate, wherein a long axis of the fin is oriented in a <110> crystallographic direction of the substrate, and performing an epitaxial deposition process using a combination of silane (SiH₄), dichlorosilane (SiH₂Cl₂), germane (GeH₄) and hydrogen to form a silicon germanium (Si₍₁₋ₓ₎Geₓ) epi semiconductor material around the fin, wherein the flow rate of dichlorosilane used during the epitaxial deposition process is equal to 10-90% of the combined flow rate of silane and dichlorosilane.

Yet another illustrative embodiment includes, among other things, forming a fin in a semiconductor substrate and performing a sequential epitaxial deposition process to form an epi semiconductor material around the fin, wherein the sequential deposition process comprises performing at least one first deposition process using one of silane (SiH₄) or dichlorosilane (SiH₂Cl₂) in combination with germane (GeH₄) and a carrier gas to form a first portion of the epi semiconductor material and, after completing the first deposition process, performing at least one second deposition process using the other of silane (SiH₄) or dichlorosilane (SiH₂Cl₂) in combination with germane (GeH₄) and a carrier gas to form a second portion of the epi semiconductor material on the first portion of the epi semiconductor material.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1F depict the formation of an epitaxial semiconductor material on the fins of an illustrative prior art FinFET device; and

FIGS. 2A-2H depict various illustrative methods of forming epitaxial semiconductor cladding material on fins of a FinFET semiconductor device.

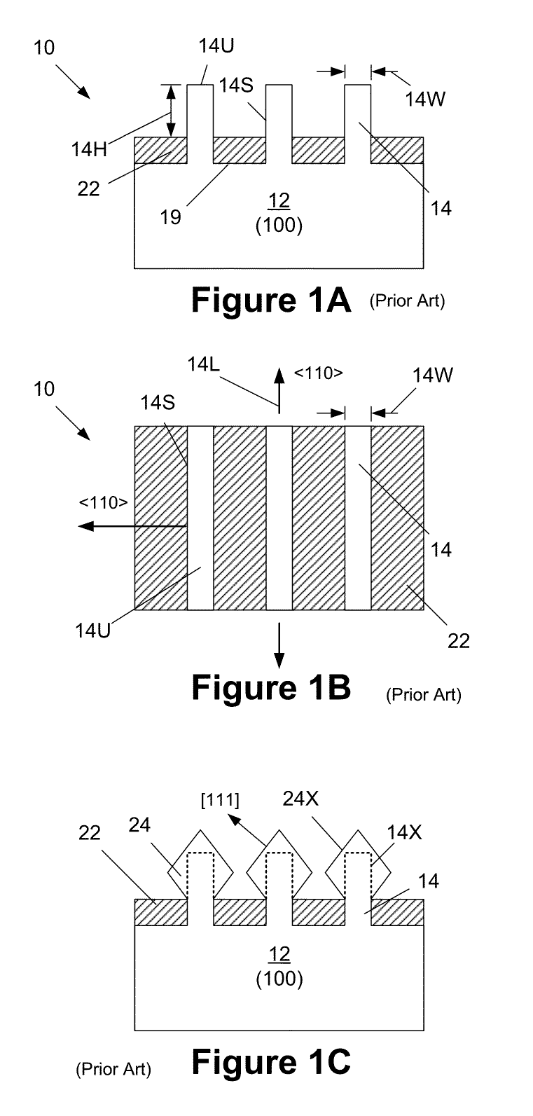

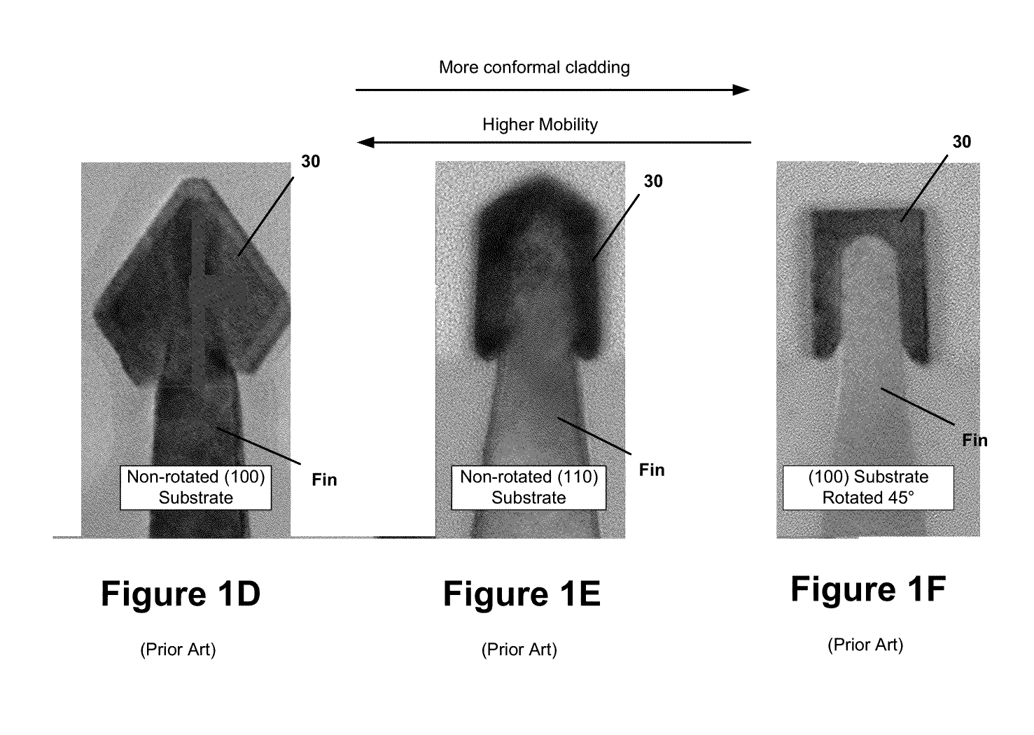

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming epitaxial semiconductor cladding material on fins of a FinFET semiconductor device. The cladding material may be formed for the channel region of the device, the source/drain regions for the device, or both. The method disclosed herein may be employed in manufacturing either an N-type device or a P-type device, and the gate structure of such devices may be formed using either so-called “gate-first” or “replacement gate” (“gate-last”) techniques. As will be readily apparent to those skilled in the art upon a complete reading of the present application, the present method is applicable to a variety of devices, including, but not limited to, logic devices, memory devices, etc., and the methods disclosed herein may be employed to form N-type or P-type semiconductor devices. With reference to the attached figures, various illustrative embodiments of the methods and devices disclosed herein will now be described in more detail.

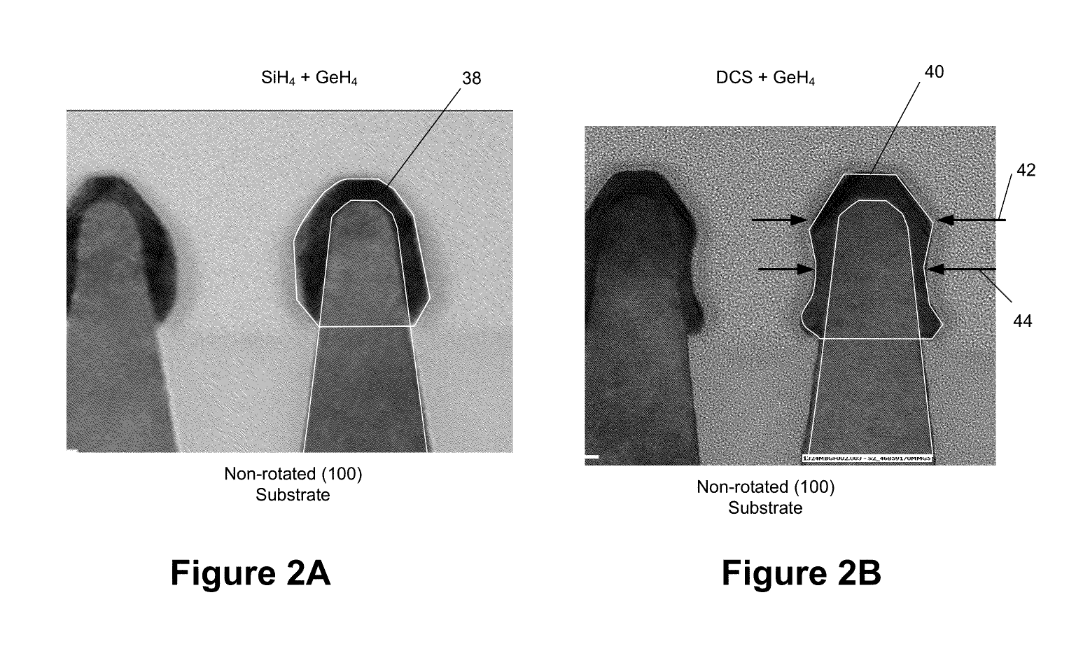

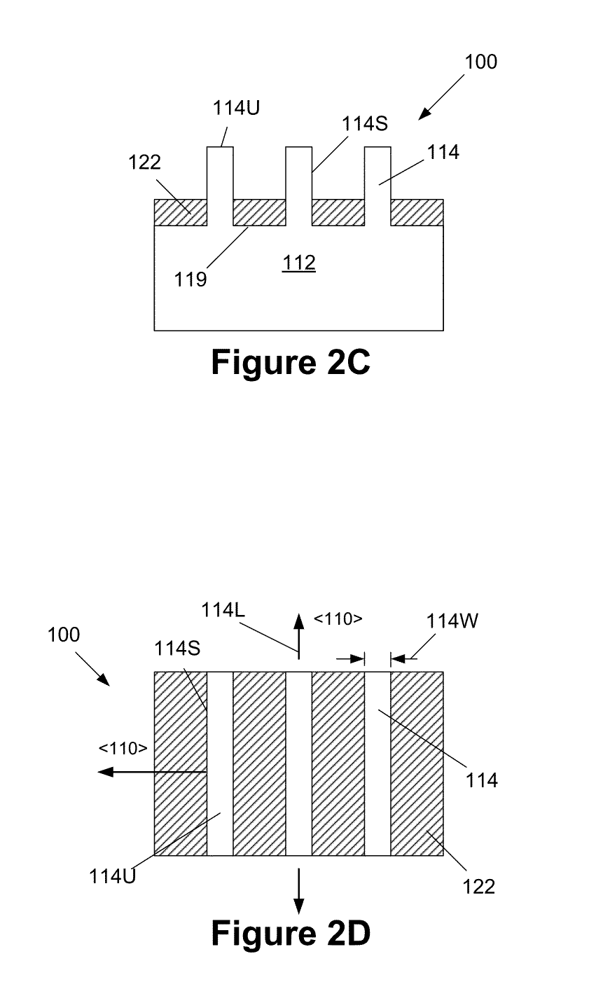

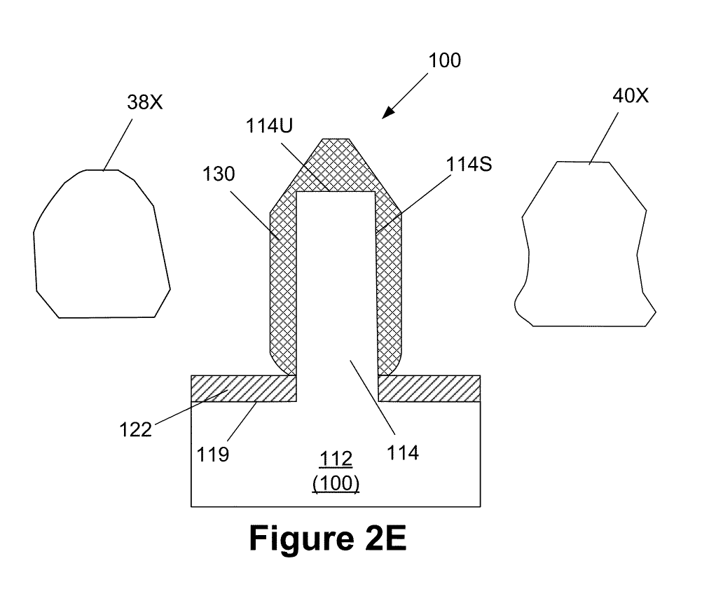

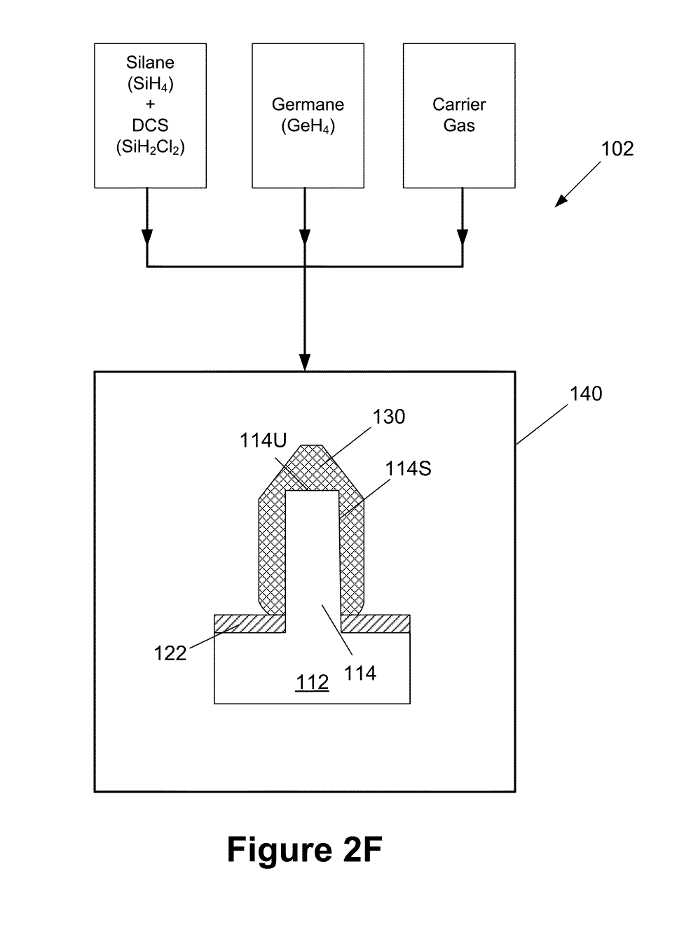

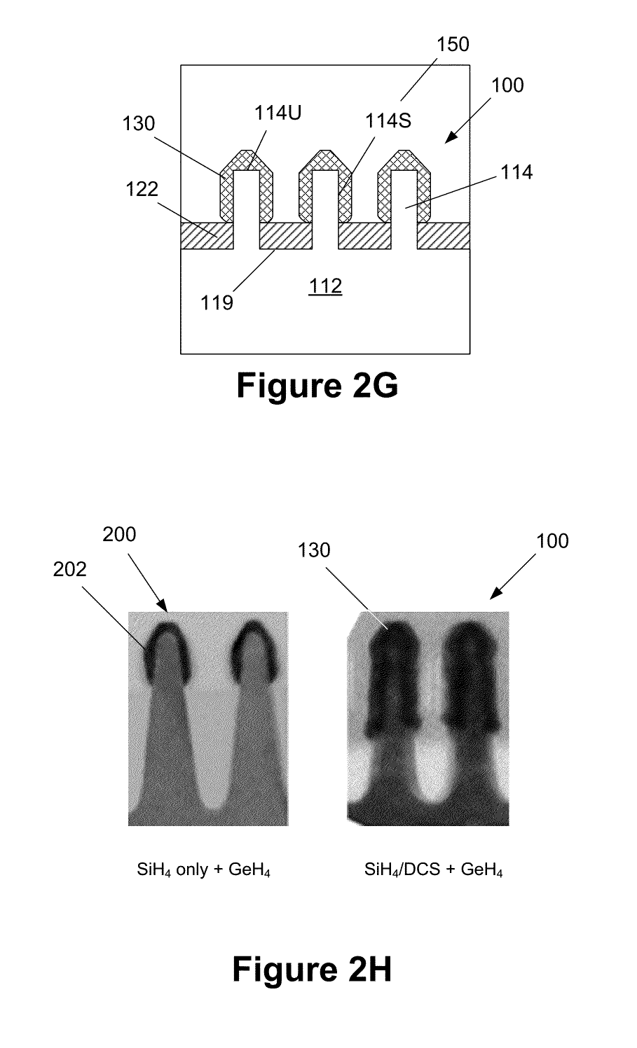

FIGS. 2A-2B are TEM photographs that depict the formation of an epi silicon-germanium (SiGe_{0.75}) material on a non-rotated (100) silicon substrate. The epi SiGe_{0.75} material 38 shown in FIG. 2A was formed using silane (SiH₄) (silicon source) and germane (GeH₄) (germanium source) as precursor gases and hydrogen as a carrier gas. The epi silicon-germanium (SiGe_{0.75}) 40 shown in FIG. 2B was formed using dichlorosilane (“DCS”; SiH₂Cl₂) (silicon source) and germane (GeH₄) (germanium source) as precursor gases and hydrogen as a carrier gas. The inventors observed that, while the epi materials 38 and 40 do not exhibit the desired conformal and substantially uniform thickness for the epi material, the use of different precursors can dramatically change the profile or configuration (outlined in white lines) of the epi cladding material. For example, with reference to FIG. 2B, note the increased thickness of the epi material at the location 42 relative to the substantially lesser thickness of the epi material 40 at the location 44. Such thickness variations would make the epi material 40 undesirable for use in the channel of a FinFET device due to the undesirable variation in the threshold voltage of the device that would be caused by the non-uniform thickness of the epi material 40. The epi semiconductor material 38 shown in FIG. 2A also exhibits undesirable thickness variations.

The inventors have discovered that, quite unexpectedly, in lieu of using only silane or only DCS as the source of silicon when forming a silicon germanium (Si₍₁₋ₓ₎Geₓ) epitaxial cladding material on a silicon fin (as depicted in FIGS. 2A and 2B above, respectively), a more uniform silicon germanium (Si(₁₋ₓGeₓ) epitaxial cladding material may be formed when using a combination of both silane and DCS, in specific ratios, and germane when forming such a silicon germanium (Si₍₁₋ₓ₎Geₓ) epitaxial cladding material on a silicon fin. In another embodiment, the inventors have discovered that performing a sequential deposition process using silane and DCS (in any order) along with germane results in a more uniform epi cladding material. As described more fully below, it is believed that by using the combination of both silane and DCS as the sources of silicon in the epi deposition process, the resulting configuration of the silicon germanium (Si(₁₋ₓGeₓ) epitaxial cladding material reflects a combination of the profiles that were typically achieved when using only silane or only DCS as the source of silicon in the epi deposition process. The newly discovered methods disclosed herein produced a more uniform and conformal silicon germanium (Si(₁₋ₓGeₓ) epitaxial cladding material that may be useful in channel regions of a FinFET device and/or overcome or reduce some of the problems discussed above with respect to formation of prior art epi cladding materials in the source/drain regions of the FinFet device.

FIGS. 2C (cross-sectional view) and 2D (plan view) depict an illustrative FinFET semiconductor device 100 that may be formed in accordance with the methods disclosed herein. The device 100 is formed above a semiconductor substrate 112. The illustrative substrate 112 may be a bulk semiconductor substrate, or it may be the active layer of a so-called SOI (silicon-on-insulator) substrate or a so-called SGOI (silicon/germanium on insulator) substrate. Thus, the terms “substrate,” “semiconductor substrate” or “semicon-ducting substrate” should be understood to cover all semiconductor materials and all forms of such semiconductor materials. The device 100 may be either a P-type FinFET device or an N-type FinFET device.

At the point of fabrication depicted in FIGS. 2C-2D, a plurality of trenches 119 were formed in a standard (100) silicon substrate 112 to define the initial structure of the simplistically depicted fins 114, having sidewalls 114S and an upper surface 114U. After the trenches 119 were formed, a layer of insulating material 122, such as silicon dioxide, was formed so as to overfill the trenches 119. Thereafter, a CMP process and an etch-back process were performed to recess the layer of insulating material 122 between the fins 114 and thereby expose the upper portions of the fins 114, which corresponds to the final fin height of the fins 114. As depicted in FIG. 2D, the axial length direction 114L of the fins 114 corresponds to the direction of current travel in the device 100 when it is operational.

As indicated in FIGS. 2C-2D, for a (100) silicon substrate 112, in traditional manufacturing techniques, the substrate 112 is oriented during manufacturing of the device 100 such that the sidewalls 114S of the fins 114 are oriented in the <110> direction, while the long axis 114L of the fins 114 is also oriented in the <110> direction. Of course, in the case where the fins 114 have a tapered cross-sectional configuration as opposed to the idealized rectangular cross-sectional configuration depicted herein, the sidewalls 114S of such tapered fins may be positioned slightly out of the <110> direction due to the tapered shape of the tapered fins.

As used herein and in the claims, the term “fin” or “fins” should be understood to mean a three-dimensional structure that is comprised, in whole or part, of the material of the substrate. That is, in one example, the fins 114 may have a substantially uniform construction, i.e., they may be formed entirely of the material of the substrate 112, e.g., silicon. Thereafter, epi semiconductor material may be formed on exposed surfaces of the fins 114 using the methods disclosed herein. Additionally, in one embodiment, the silicon germanium (Si₍₁₋ₓ₎Geₓ) epitaxial cladding material disclosed herein may be formed around the entire axial length 114L of the fins 114 prior to the formation of any type of gate structure. In another embodiment, the methods disclosed herein may be used to form epi semiconductor material in the source/drain regions of the device, irrespective of whether epi semiconductor material is formed in the channel region of the device 100. In yet another embodiment, a condensation process may be performed to form fins comprised of homogenous silicon germanium (Si₍₁₋ₓ₎Geₓ) material.

FIG. 2E depicts one illustrative example disclosed herein of how the fins 114 of the FinFET device 100 may be oriented relative to the crystallographic orientation of the substrate material so as to produce the conformal more uniform silicon germanium (Si₍₁₋ₓ₎Geₓ) epitaxial cladding material disclosed herein. FIG. 2E depicts an illustrative substrate 112 having a (100) crystalline structure. Such (100) silicon substrates are well known in the art and are generally commercially available from a number of manufacturers. As indicated in FIGS. 2C-D, for a (100) silicon substrate 112, in one illustrative process flow, the substrate 112 is oriented during manufacturing of the device 100 such that the sidewalls 114S of the fins 114 are oriented in the <110> direction, and the long axis or centerline 114L of the fins 114 is also oriented in the <110> direction. Of course, in the case where the fins 114 have a tapered cross-sectional configuration as opposed to the idealized rectangular cross-sectional configuration shown in FIG. 2C, the sidewalls 114S of the fins may be positioned slightly out of the <110> direction due to the tapered shape of the tapered fins.

One illustrative process flow that may be employed to form the device 100 on a non-rotated (100) substrate 112 will now be described with reference to the following drawings. Of course, other process flows may be used to form the fins 114 of the device 100 disclosed herein. Thus, the methods and devices disclosed herein should not be considered to be limited to the illustrative process flow described herein.

FIG. 2E depicts the device 100 after the methods disclosed herein were performed to form a silicon germanium (Si₍₁₋ₓ₎Geₓ) epitaxial cladding material 130 on the exposed surfaces 114S and upper surface 114U of the fin 114. As depicted, using the methods disclosed herein, the epitaxial semiconductor cladding material 130 is more conformal in nature and has a more uniform thickness, especially along the sidewalls of the fin 114, as compared to corresponding epitaxial semiconductor cladding material deposited on a fin using the prior art techniques discussed in the background section of this application. For reference purposes, FIG. 2E also depicts the outlines 38X and 40X of the epi semiconductor materials 38 and 40, respectively, as shown in FIGS. 2A (silane only as silicon source) and 2B (DCS only as silicon source).

FIG. 2F is one illustrative embodiment of a system 102 that may be employed to form the epitaxial semiconductor cladding material 130 on the fin 114. In general, the system 102 is comprised of a process chamber 140 and sources of silane, DCS, germane and a carrier gas, such as hydrogen. Of course, the system 102 includes many other features and structures, such as valves, piping, power supply, vents, a support stage, etc., which are not depicted so as not to obscure the presently disclosed inventions. Additionally, although the silane and DCS are depicted as coming from a single source, the two gases may be supplied from separate, individual sources and combined prior to entering the process chamber 140 or they may be separately introduced into the process chamber 140.

The parameters of the epi process may vary depending upon the particular application. For example, in one illustrative embodiment where the epitaxial semiconductor cladding material 130 is silicon germanium (Si₍₁₋ₓ₎Geₓ) that is formed on a silicon fin 114, the epi process may be performed under the following conditions:

Pressure=10-200 Torr, with about 50 Torr being one preferred example;

Temperature=350-750° C., with about 405° C. being one preferred example;

Carrier Gas=Hydrogen at a flow rate between 3,000-50,000 sccm, with about 20,000 sccm being one preferred example;

DCS=5-100 sccm, with about 20 sccm being one preferred example;

Silane=5-100 sccm, with about 40 sccm being one preferred example; and

Germane=50-500 sccm (10% diluted in H₂), with about 150 sccm being one preferred example.

In general, the inventors have discovered that forming the more uniform epitaxial semiconductor cladding material 130 disclosed herein may be achieved when the epi deposition process is performed when the amount of DCS is set to be about 10-90% of the total combined flow rate of both DCS and silane. In the preferred example mentioned above, the DCS is 33.3% (20 sccm) of the combined flow rate of both the DCS and the silane (60 sccm). The inventors have discovered that a high germane versus silane and DCS ratio (meaning higher germanium content SiGe materials) may be preferred for more uniform epitaxial cladding. In the preferred example, a germane versus silane and DCS ratio 150/60 is used to form Si_{0.25}Ge_{0.75} material.

In another illustrative embodiment, a sequential deposition process may be performed using silane and DCS in any desired order. For example, in one embodiment, the epi semiconductor material 130 may be formed by performing a first chemical vapor deposition process using silane, germane and a carrier gas to form a first portion of the epitaxial semiconductor cladding material 130. Thereafter, a second chemical vapor deposition process may be performed using DCS, germane and a carrier gas to form a second portion of the epitaxial semiconductor cladding material 130 on the previously-formed first portion of epitaxial semiconductor cladding material 130. Of course, if desired, the DCS-based deposition sequence could be performed prior to the silane-based deposition sequence. The sequential deposition process may be repeated as often as needed to develop the desired thickness of the epi semiconductor material 130. Importantly, this sequential deposition process may be performed in a single process chamber and without breaking the processing ambient and exposing the device to ambient room conditions. The gas flow rates and process conditions for this sequential deposition embodiment are the same as those noted above, with the DCS or silane (as the case may be) omitted.

As noted above, it is believed that by using the combination of both silane and DCS as the source of silicon in the epi deposition process, the resulting configuration of the silicon germanium (Si₍₁₋ₓ₎Geₓ) epitaxial cladding material 130 reflects an unexpected combination of the profiles that were typically achieved when using only silane or only DCS as the source of silicon in the epi deposition process that included germane. Prior to the discovery of the present invention, process engineers knew that a source of silicon was required to form epi silicon germanium material, and silane and DCS were simply viewed as being substantially interchangeable sources of silicon. Prior to the present discovery, there was no perceived benefit or motivation to use multiple sources of silicon in the epi formation process.

In one embodiment, the epitaxial semiconductor cladding material 130 is formed along the entire axial length 114L of the fin 114 and at least a portion of the cladding material 130 will be part of the channel region of the device 100. In one embodiment, when formed in the channel region of the device 100, the epitaxial semiconductor cladding material 130 may have a thickness that falls within the range of about 2-10 nm. After the formation of the epitaxial semiconductor cladding material 130, traditional processing operations may be performed to complete the fabrication of the device 100. For example, as shown in FIG. 2G, an illustrative gate structure 150 may be formed on the device 100 above and around the epitaxial semiconductor cladding material 130 that is formed on fins 114. The gate structure 150 is intended to be representative in nature of any gate structure that may be formed on semiconductor devices. The illustrative gate structure 150 may be formed using well-known techniques. i.e., gate-first or gate-last techniques. Of course, the materials of construction used for the gate structure 150 on a P-type FinFET device may be different than the materials used for the gate structure 150 on an N-type FinFET device. In one illustrative embodiment, the schematically depicted gate structure 150 includes an illustrative gate insulation layer (not separately shown) and an illustrative gate electrode (not separately shown). The gate insulation layer may be comprised of a variety of different materials, such as, for example, silicon dioxide, a so-called high-k (k greater than 10) insulation material (where k is the relative dielectric constant), etc. Similarly, the gate electrode may also be of a variety of conductive materials, such as polysilicon or amorphous silicon, or it may be comprised of one or more metal layers that act as the gate electrode.

In another embodiment, the methods disclosed herein may be employed to form the epitaxial semiconductor material 130 in both the channel region of the device as well as in the source/drain regions of the device. The epi material 130 in the source/drain regions may be doped with the appropriate dopant materials in situ, e.g., P-type dopants for a P-type device or N-type dopants for an N-type device. In this embodiment, the epitaxial semiconductor cladding material 130 may initially be formed so as to cover the entire axial length 114L of the fins 114. Thereafter, the above-described gate structure 150 may be formed over a portion of the fins (the channel region) and sidewall spacers may be formed adjacent the gate structure. At that point, a cleaning process may be performed on the source/drain regions of the device in advance of forming epi material in the source/drain regions. This cleaning process may or may not remove all of the epitaxial semiconductor cladding material 130 that was initially formed on the fins 114. Thereafter, the methods disclosed herein may be performed to form epitaxial semiconductor cladding material 130 in the source/drain regions of the device 100. In this illustrative embodiment, the epitaxial semiconductor cladding material 130 in the channel region of the device 100 may have a thickness of about 2-10 nm, while the epitaxial semiconductor cladding material 130 formed in the source/drain regions may be significantly thicker, e.g., 5-60 nm. By virtue of the highly conformal nature of the epitaxial semiconductor cladding material 130 formed as disclosed herein, a highly desirable and relatively thin layer of epitaxial semiconductor cladding material 130 may be formed in the channel region of the device, and a significant amount of epitaxial semiconductor cladding material 130 may be formed in the source/drain regions while reducing the chances of undesirable fin merger occurring.

In yet another embodiment, the epitaxial semiconductor cladding material 130 disclosed herein may be formed only in the source/drain regions of the device 100, i.e., after the above-described gate structure 150 is formed and associated sidewall spacers are formed adjacent the gate structure. In such a case, the epitaxial semiconductor cladding material 130 would not be positioned in the channel region of the device 100. In this embodiment, the gate structure 150 is formed so as to cover the bare fin 114 in the channel region of the device and the sidewall spacers are then formed adjacent the gate structure. At that point, a cleaning process may be performed on the source/drain regions of the device. Thereafter, the methods disclosed herein may be performed to form epitaxial semiconductor cladding material 130 in the source/drain regions of the device 100. As noted above, by virtue of the highly conformal nature of the epitaxial semiconductor cladding material 130 formed as disclosed herein, a significant amount of epitaxial semiconductor cladding material 130 may be formed in the source/drain regions while reducing the chances of undesirable fin merger occurring.

FIG. 2H are TEM photographs of two different devices 100, 200. For the device 100 (on the right-hand side) the methods disclosed herein were employed in forming the more conformal epitaxial semiconductor cladding material 130 described herein. For the device 200 (on the left), the semiconductor cladding material 202 was formed using a process wherein only silane was used as the silicon source. As depicted, the epitaxial semiconductor cladding material 130 is very conformal, and certainly much more conformal than the semiconductor material 202 that was formed using silane only as the source of silicon.

Additionally, a fin condensation thermal anneal process may be performed on the device after the formation of the epitaxial semiconductor cladding material 130 so as to further increase the conformal nature of the epitaxial semiconductor cladding material 130. In one illustrative embodiment, the fin condensation thermal anneal process may be performed at a temperature that falls within the range of about 500-800° C. using an RTA furnace, a laser anneal process or a traditional furnace, depending upon the particular application. The fin condensation thermal anneal process must be performed in an oxidizing processing ambient. During the fin condensation thermal anneal process, some of the outer portions of the overall fin structure is oxidized, thereby producing a thinner, more condensed fin.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a FinFET device, comprising:
forming a fin in a semiconductor substrate; and
performing an epitaxial deposition process using a combination of silane (SiH₄), dichlorosilane (SiH₂Cl₂), germane (GeH₄) and a carrier gas to form an epi semiconductor material around said fin, wherein the flow rate of dichlorosilane used during said epitaxial deposition process is equal to 10-90% of the combined flow rate of silane and dichlorosilane.

2. The method of claim 1, wherein said substrate is a (100) silicon substrate and a long axis of said fin is oriented in a <110> crystallographic direction of said substrate.

3. The method of claim 1, wherein said epi semiconductor material is silicon germanium (Si₍₁₋ₓ₎Geₓ).

4. The method of claim 1, wherein performing said epitaxial deposition process comprises performing said epitaxial deposition process under the following process conditions: pressure: 10-200 Torr; temperature: 350-750° C.; carrier gas: hydrogen at a flow rate of between 3,000-50,000 sccm; silane at a flow rate of between 5-100 sccm; dichlorosilane at a flow rate of between 5-100 sccm; and germane at a flow rate of between 50-500 sccm.

5. The method of claim 1, wherein performing said epitaxial deposition process comprises performing said epitaxial deposition process under the following process conditions: pressure: about 50 Torr; temperature: about 405° C.; carrier gas: hydrogen at a flow rate of about 20,000 sccm; silane at a flow rate of about 40 sccm; dichlorosilane at a flow rate of about 20 sccm; and germane at a flow rate of about 150 sccm.

6. The method of claim 1, wherein said epi semiconductor material is formed on an entire axial length of said fin.

7. The method of claim 6, wherein the method further comprises, after formation of said epi semiconductor material, forming a gate structure around a portion of said fin and said epi semiconductor material and forming sidewall spacers adjacent said gate structure.

8. The method of claim 7, wherein the method further comprises performing an additional epitaxial deposition process described in claim 1 to form said epi semiconductor material around said fin in the source/drain regions of said device.

9. The method of claim 1, wherein, prior to performing said epitaxial deposition process, the method further comprises forming a gate structure around a portion of said fin, forming sidewall spacers adjacent said gate structure and wherein performing said epitaxial deposition process comprises performing said epitaxial deposition process to form said epi semiconductor material around said fin in said source/drain regions of the device.

10. The method of claim 1, further comprising performing a condensation thermal anneal process on said epi semiconductor material in an oxidizing process ambient.

11. A method of forming a FinFET device, comprising:
forming a fin in a (100) silicon substrate, wherein a long axis of said fin is oriented in a <110> crystallographic direction of said substrate; and
performing an epitaxial deposition process using a combination of silane (SiH₄), dichlorosilane (SiH₂Cl₂), germane (GeH₄) and hydrogen to form a silicon germanium (Si₍₁₋ₓ₎Geₓ) epi semiconductor material around said fin, wherein the flow rate of dichlorosilane used during said epitaxial deposition process is equal to 10-90% of the combined flow rate of silane and dichlorosilane.

12. The method of claim 11, wherein performing said epitaxial deposition process comprises performing said epitaxial deposition process under the following process conditions: pressure: 50-2000 Torr; temperature: 350-750° C.; hydrogen at a flow rate of between 3,000-50,000 sccm; silane at a flow rate of between 5-100 sccm; dichlorosilane at a flow rate of between 5-100 sccm; and germane at a flow rate of between 50-500 sccm.

13. The method of claim 11, wherein performing said epitaxial deposition process comprises performing said epitaxial deposition process under the following process conditions: pressure: about 50 Torr; temperature: about 405° C.; hydrogen at a flow rate of about 20,000 sccm; silane at a flow rate of about 40 sccm; dichlorosilane at a flow rate of about 20 sccm; and germane at a flow rate of about 150 sccm.

14. The method of claim 11, wherein said epi semiconductor material is formed on an entire axial length of said fin.

15. The method of claim 14, wherein the method further comprises, after formation of said epi semiconductor material, forming a gate structure around a portion of said fin and said epi semiconductor material and forming sidewall spacers adjacent said gate structure.

16. The method of claim 15, wherein the method further comprises performing an additional epitaxial deposition process described in claim 1 to form said epi semiconductor material around said fin in the source/drain regions of said device.

17. The method of claim 11, wherein, prior to performing said epitaxial deposition process, the method further comprises forming a gate structure around a portion of said fin, forming sidewall spacers adjacent said gate structure and wherein performing said epitaxial deposition process comprises performing said epitaxial deposition process to form said epi semiconductor material around said fin in the source/drain regions of said device.

18. The method of claim 11, further comprising performing a condensation thermal anneal process on said epi semiconductor material in an oxidizing process ambient.

19. A method of forming a FinFET device, comprising:
forming a fin in a semiconductor substrate; and
performing a sequential epitaxial deposition process to form an epi semiconductor material around said fin, wherein said sequential deposition process comprises:
performing at least one first deposition process using one of silane (SiH₄) or dichlorosilane (SiH₂Cl₂) in combination with germane (GeH₄) and a carrier gas to form a first portion of said epi semiconductor material; and
after completing said first deposition process, performing at least one second deposition process using the other of silane (SiH₄) or dichlorosilane (SiH₂Cl₂) in combination with germane (GeH₄) and a carrier gas to form a second portion of said epi semiconductor material on said first portion of said epi semiconductor material.

20. The method of claim 19, wherein said substrate is a (100) silicon substrate and a long axis of said fin is oriented in a <110> crystallographic direction of said substrate.

21. The method of claim 19, wherein said epi semiconductor material is silicon germanium (Si₍₁₋ₓ₎Geₓ).

22. The method of claim 19, wherein said epi semiconductor material is formed on an entire axial length of said fin.

23. The method of claim 22, wherein said method further comprises, after formation of said epi semiconductor material, forming a gate structure around a portion of said fin and said epi semiconductor material and forming sidewall spacers adjacent said gate structure.

24. The method of claim 23, wherein the method further comprises performing an additional epitaxial deposition process described in claim 1 to form said epi semiconductor material around said fin in the source/drain regions of said device.

25. The method of claim 19, wherein, prior to performing said epitaxial deposition process, the method further comprises forming a gate structure around a portion of said fin, forming sidewall spacers adjacent said gate structure and wherein performing said epitaxial deposition process comprises performing said epitaxial deposition process to form said epi semiconductor material around said fin in the source/drain regions of said device.

26. The method of claim 19, further comprising performing a condensation thermal anneal process on said epi semiconductor material in an oxidizing process ambient.

27. The method of claim 19, wherein said at least one first and second deposition processes are performed without exposing said fin to ambient room conditions between said first and second deposition processes.
